(19) United States
(12) Patent Application Publication
(10) Pub. No.: US 2021/0280725 A1
(43) Pub. Date: Sep. 9, 2021

(54) LOW-COST, CRACK-TOLERANT, SCREEN-PRINTABLE METALLIZATION FOR INCREASED MODULE RELIABILITY

(71) Applicants: UNM RAINFOREST INNOVATIONS, Albuquerque, NM (US); AIR FORCE RESEARCH LAB, Albuquerque, NM (US)

(72) Inventors: Sang M. HAN, Albuquerque, NM (US); Omar Kamal ABUDAYYEH, Albuquerque, NM (US); Andre CHAVEZ, Albuquerque, NM (US); David M. WILT, Albuquerque, NM (US)

(21) Appl. No.: 17/257,607

(22) PCT Filed: Jun. 28, 2019
(86) PCT No.: PCT/US2019/039850

§ 371 Date: Jan. 4, 2021

Related U.S. Application Data
(60) Provisional application No. 62/694,337, filed on Jul. 5, 2018.

(51) Int. Cl. H01L 31/0224; H01L 31/0216; H01L 31/18; H01B 1/04

(52) U.S. Cl. CPC H01L 31/022425; H01B 1/04; H01L 31/18; H01L 31/02168

(57) ABSTRACT

A metal matrix composite paste is provided for screen printing metal matrix composite contacts in a photovoltaic cell. The metal matrix composite paste includes a plurality of functionalized multi-walled carbon nanotubes in a metal paste. Because the metal matrix composite paste can have similar mechanical and chemical properties to a metal paste, it can be incorporated into standard metallization processes. The metal matrix composite contacts formed from the metal matrix composite paste can have increased ductility and self-healing capability to electrically bridge a gap caused by physical fracture of a busbar or gridline.

### CROSS-REFERENCE TO RELATED APPLICATIONS

This application is a 371 National Phase application of International Application No. PCT/US2019/039850, filed Jun. 28, 2019, and published as WO 2020/009936 A1 on Jan. 9, 2020, which claims priority to U.S. Provisional Patent Application No. 62/694,337 filed on Jul. 5, 2018, all of which are hereby incorporated by reference in their entireties.

### GOVERNMENT FUNDING

This invention was made with government support provided by the Department of Energy under Grant No. AGJ-8-70325-01. The Government has certain rights in the invention.

### TECHNICAL FIELD

The present disclosure is directed to printable metal contacts and, more particularly, to screen printable metal matrix composites and method for forming them.

### BACKGROUND

Space vehicles are primarily powered by multi-junction solar cells due to their high performance with efficiencies near 30% under 1-sun Air Mass 0 (AM0) spectrum and good radiation tolerance in the space environment. While multi-junction cells provide a high efficiency, cracks (also referred to herein as microcracks) can develop in crystalline photovoltaic (PV) cells due to various reasons including growth defects, film stress by lattice mismatch, and mechanical stress introduced during fabrication, shipping, installation, launch, and operation. These cracks can electrically isolate fragmented parts of the PV cell, which in turn can lead to a substantial power loss. Similarly, for terrestrial silicon-based PV cells, cracks have been shown to reduce mechanical stability and significantly degrade performance both at the cell and the module level. For solar electricity to successfully compete with the fossil-fuel-based electricity generation, highly durable PV modules are needed. The durability of PV modules is commonly measured by their degradation rate, a slow gradual loss of performance over time. High degradation rates translate to reduced power generation and, therefore, reduced cost effectiveness. One way to increase the cost effectiveness of solar power is to reduce the degradation rate of PV cells and modules to extend their lifetimes.

Printed metal contacts for PV cells and modules can be formed by several techniques including screen printing, inkjet printing, and extrusion. A printable metal paste is typically used in each of these techniques during the metallization process. In screen printing, for example, metal contacts such as gridlines and busbars are formed by printing and firing the metal paste on silicon (Si) substrates. A common degradation mechanism of PV modules today is hot spots, often induced by cracks in metal contacts of the PV cell and also caused by shadowing and soiling. Gridlines and busbars, once cracked or severed, experience immediate and irrecoverable loss of electrical continuity. Even before turning into hot spots, these cracks lead to high series resistance, reduced efficiency, and lost energy.

Therefore, more durable contacts and improved printable pastes for forming more durable contacts for photovoltaic cells would be desirable.

### SUMMARY

According to the present teachings, a photovoltaic cell is provided. The photovoltaic cell includes a substrate, an anti-reflection coating disposed on the substrate and a metal matrix composite contact disposed on the anti-reflection coating. The metal matrix composite contact includes a metal and a plurality of multi-walled carbon nanotubes (CNTs) distributed in the metal, wherein the metal of the metal matrix composite contact electrically connects to the substrate through the anti-reflection coating.

According to the present teachings, a method for forming a paste for screen printing contacts is provided. The method includes providing a plurality of multi-walled carbon nanotubes and functionalizing a surface of the plurality of multi-walled carbon nanotubes. The method further includes mixing the plurality of functionalized multi-walled carbon nanotubes with a metal paste to form a metal matrix composite (MMC) paste. Optionally, the method can further include forming a solution comprising the plurality of functionalized multi-walled carbon nanotubes and a solvent prior to mixing the plurality of functionalized multi-walled carbon nanotubes with a metal paste.

According to the present teachings, a metal matrix composite paste is provided. The metal matrix composite paste includes a metal paste and a plurality of multi-walled carbon nanotubes, wherein a surface of the plurality of multi-walled carbon nanotubes is functionalized with carboxylic or amine functional groups.

According to the present teachings, a method for forming an electrical contact in a photovoltaic device is provided. The method includes providing a substrate and depositing a dielectric layer on the substrate. The method further includes screen printing on the dielectric layer a metal matrix composite paste comprising a metal paste and a plurality of multi-walled carbon nanotubes, wherein a surface of the multi-walled carbon nanotubes is functionalized with carboxylic or amine functional groups and firing the metal matrix composite paste to form an electrical contact.

### BRIEF DESCRIPTION OF THE DRAWINGS

The accompanying drawings, which are incorporated in and constitute a part of this specification, illustrate the present disclosure and together with the description, serve to explain the principles of the present disclosure.

FIG. 1 schematically depicts a method for forming a metal matrix composite paste in accordance with the present teachings;

FIG. 2 schematically depicts a portion of a PV cell including a bulbar and gridlines formed from a metal matrix composite in accordance with the present teachings;

FIG. 3 schematically depicts a portion of a gridline formed from a metal matrix composite including a crack in accordance with the present teachings;

FIG. 4 plots a firing profile for three screen printed metal matrix composite contacts in accordance with the present teachings;

FIG. 5 demonstrates the gap bridging capability of the metal matrix composite contacts in accordance with the present teachings by plotting electrical resistance as a function of the size of a gap;

FIG. 6A demonstrates the self-healing capability of a metal matrix composite contacts including Paste A in accordance with the present teachings by plotting displacement versus strained-to-failure and closed-gap cycle;

FIG. 6B demonstrates the self-healing capability of a metal matrix composite contacts including Paste B in accordance with the present teachings by plotting displacement versus strained-to-failure and closed-gap cycle;

FIG. 6C demonstrates the self-healing capability of a metal matrix composite contacts including Paste C in accordance with the present teachings by plotting displacement versus strained-to-failure and closed-gap cycle.

### DETAILED DESCRIPTION OF THE INVENTION

Reference will now be made in detail to exemplary implementations of the present disclosure, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary implementations in which the present disclosure may be practiced. These implementations are described in sufficient detail to enable those skilled in the art to practice the present disclosure, and it is to be understood that other implementations may be utilized and that changes may be made without departing from the scope of the present disclosure. The following description is, therefore, merely exemplary.

For photovoltaic (PV) electricity to successfully compete with fossil fuel based electricity generation, highly durable PV modules are needed. Cracks in the metallization, for example gridlines and busbars, are a common degradation mode in PV cells and modules. Disclosed herein are metal matrix composite (MMC) pastes that can be used to form metal matrix composite contacts with improved properties that resist cracks and self-heal after cracking. The disclosed metal matrix composite paste includes functionalized carbon nanotubes (CNTs) incorporated into a metal paste. Because the metal matrix composite pastes can have a similar chemical and mechanical properties to conventional metal pastes, the disclosed metal matrix composite pastes can be used in established metallization workflows with no or minimal changes to the processes.

Also provided herein are metal matrix composite contacts for use in photovoltaic devices. Metallization using the disclosed metal matrix composites pastes can form metal matrix composite contacts, such as gridlines (also referred to herein as fingers) and busbars for PV cells and modules with enhanced toughness. Additionally, contacts formed of the disclosed metal matrix composite exhibit increased ductility and self-healing capability to electrically bridge a gap caused by physical fracture of a bulbar or gridline. When used in PV cells, modules, and systems, this can provide extended lifetimes which reduce the cost of solar energy.

As used herein, “metal-matrix composite” refers to a material comprising a plurality of multi-walled carbon nanotubes and a metal matrix.

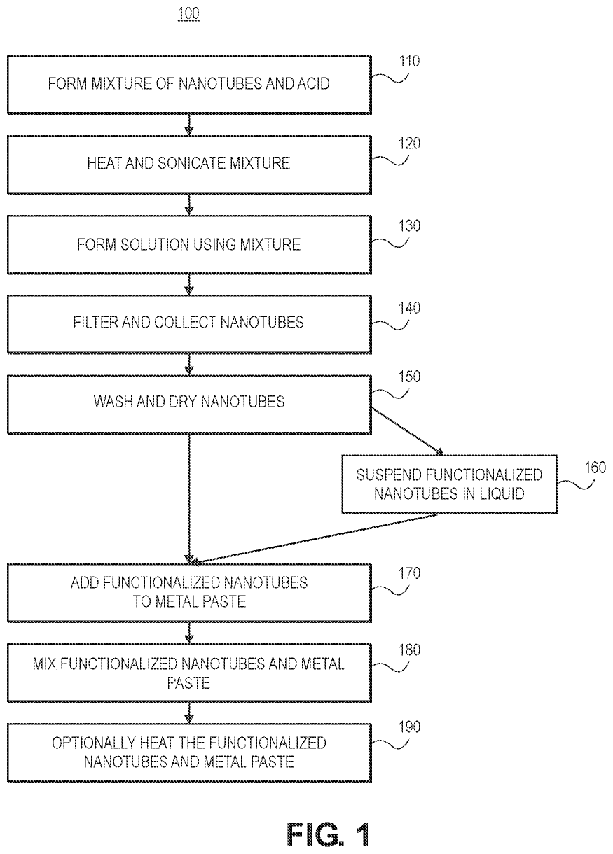

FIG. 1 depicts a method 100 for making a metal matrix composite paste according to the present disclosure. At 110 of method 100, a plurality of multi-walled carbon nanotubes is provided and combined with one or more acids to form a mixture. The one or more acids can include, but are not limited to, nitric acid (HNO₃), sulfuric acid (H₂SO₄) or combinations thereof. For example, the plurality of multi-walled carbon nanotubes can be combined in a 1:3 volumetric mixture with one or more acids. The plurality of multi-walled carbon nanotubes can have a length from about 2 to about 100 μm, or from about 10 to about 30 μm. The plurality of multi-walled carbon nanotubes can have an outside diameter from about 3 to about 170 nm, from 6 to about 80 nm, or from about 30 to about 50 nm.

At 120 of method 100, the mixture can be sonicated and heated. For example, the mixture can be sonicated at about 40 kHz to about 60 kHz for about 0.1 hours to about 3 hours at a temperature of 25° C. to about 40° C. After sonicating and heating, the mixture can be used to form a solution at 130 of method 100. The solution can be formed, for example, by adding the mixture dropwise to deionized water.

At 140 of method 100, the solution can be filtered, and the plurality of multi-walled carbon nanotubes can be collected. Filtering can be by vacuum filtering using, for example, polypropylene filter paper. The plurality of multi-walled carbon nanotubes can be washed at 150 of method 100 to remove any residual acid and then dried. The resulting functionalized carbon nanotubes includes chemical groups attached to the outer walls and ends of the plurality of multi-walled carbon nanotubes. For example, —COOH can be attached to the nanotubes for carboxylation and —NH₂ can be attached to the nanotubes for amination. Functionalizing the surface of the plurality of multi-walled carbon nanotubes with carboxylic or amine functional groups enhances the wettability of the multi-walled carbon nanotubes to various surrounding media, including polar solvents in which the functionalized multi-walled carbon nanotubes can be suspended. The choice of polar solution containing multi-walled carbon nanotubes can increase the solution miscibility with metal pastes, while appropriately adjusting rheological properties of the resulting metal matrix composite paste. The surface functionalization also impacts the adhesion strength between multi-walled carbon nanotubes and surrounding metal matrix after firing, as well as carbon nanotube-carbon nanotube interactions. Additionally, the multi-walled carbon nanotube functionalization can lead to different mechanical and electrical properties from their native, unfunctionalized form.

Optionally, at 160 of method 100, the functionalized multi-walled carbon nanotubes can be suspended in a liquid. For example, the functionalized multi-walled carbon nanotubes can be suspended in a high vapor pressure solvent including, but not limited to isopropanol, and sonicated at about 40 to about 60 kHz.

At 170 of method 100, the functionalized multi-walled carbon nanotubes can be added to a metal paste to form a metal matrix composite paste. If the functionalized multi-walled carbon nanotubes are suspended in the high vapor pressure solvent, the mixture can be added to a metal paste to form a metal matrix composite paste. The metal paste can be, for example, silver, gold, copper, or aluminum. The functionalized multi-walled carbon nanotubes can be about 0.1 to about 10 weight percent of the metal matrix composite paste. The functionalized multi-walled carbon nanotubes can further be about 1 weight percent of the metal matrix composite paste.

At 180 of method 100, the functionalized multi-walled carbon nanotubes and metal paste forming the metal matrix composite paste can be mixed. Mixing allows the high vapor pressure solvent, if present, to evaporate and minimize the impact of adding the nanotubes to the chemical and mechanical properties of the metal paste. For example, a planetary centrifugal mixer and/or a three-roll-mill type mixer can be used. The metal matrix composite paste can have a similar or same viscosity as the metal paste without the multi-walled carbon nanotubes.

Optionally, at 190 of method 100, low heating can be used to remove excess solvent or to adjust the viscosity of the metal matrix composite paste. For example, heating can be used to match the viscosity of the metal matrix composite paste to the viscosity of the metal paste without multi-walled carbon nanotubes. Heating can also be used during screen printing to increase the viscosity of the metal matrix composite paste to make screen printing easier. The viscosity can range from about 13 to about 225 Pascal-second (Pa s).

The metal matrix composite pastes disclosed herein can be screen-printed and fired, to form metal matrix composite PV contacts. Furthermore, the metal matrix composite pastes disclosed herein can be incorporated into established metallization processes, such as screen-printing, to form contacts for silicon photovoltaic cells having increased crack-tolerance and self-healing properties.

Metal Matrix Composite Paste Example

Three metal matrix composite pastes were formed in accordance with the present teachings, each including a silver paste and a plurality of functionalized multi-walled carbon nanotubes. Multi-walled carbon nanotubes were obtained from Cheap Tubes, Inc. (Cambridgeport, Vt.) having an outer diameter of 30-50 nm and a length of 10-20 μm. Three silver pastes produced by E. I. du Pont de Nemours and Company (Wilmington, Del.) were used: (1) Paste A—Dupont PV19L for p-type silicon (Si) with n⁺ emitter; (2) Paste B—Dupont PV76A for p-type Si with n⁺ emitter; and, (3) Paste C—Dupont PV3N2 for n-type Si with p⁺ emitter.

A mixture was formed by combining the multi-walled carbon nanotubes in a 1:3 volumetric mixture with concentrated HNO₃ and H₂SO₄. The mixture was sonicated at 40 kHz for 3 hours at 40° C. The mixture was then added drop-wise to deionized water, and the resulting solution was vacuum filtered using 0.2-μm-pore Polypro filter paper from Millipore Sigma (Burlington, Mass.). The multi-walled carbon nanotubes were thoroughly washed until to remove residual acid. The carboxylated multi-walled carbon nanotubes in dry form were re-suspended in isopropanol in a sonication bath. Sonication was conducted at 40 kHz for about 0.5 to 1 hour at 25 to 35° C. The multi-walled carbon nanotubes-solvent mixture was then added to the three silver (Ag) pastes at about 1 weight percent (wt %) and mixed using a planetary centrifugal mixer. The re-suspension of the carboxylated multi-walled carbon nanotubes in a high-vapor-pressure solvent facilitated the mixing. The high-vapor-pressure solvents was allowed to evaporate to minimize the impact of adding CNTs on mechanical and chemical properties of the silver pastes. Excess solvent was then ejected from the paste using low heat of about 80 to about 95 C.° to restore the original viscosity of the paste. The resulting three metal matrix composite pastes had a same viscosity as the corresponding silver pastes without the multi-walled carbon nanotubes.

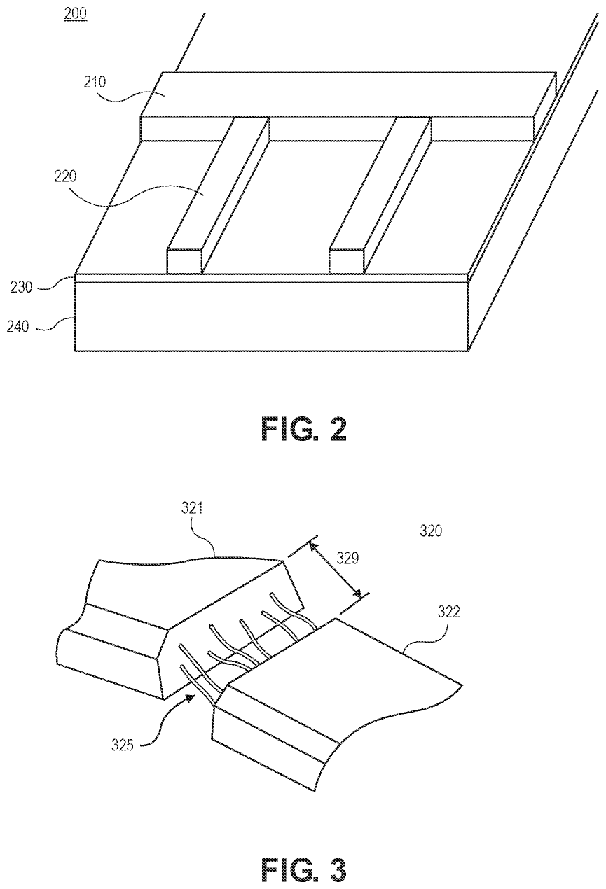

FIG. 2 schematically depicts metal matrix composite contacts on photovoltaic cells that form a PV module in accordance with the present disclosure. A PV cell 200 can include an electrical contact, such as a busbar 210 and a gridline 220. Gridlines are also referred to herein as fingers. Busbar 210 and gridline 220 are disposed on a dielectric layer 230. Dielectric layer 230 is disposed on a substrate 240. Substrate 240 can be formed of, for example, silicon. Dielectric layer 230, disposed on a substrate 240, can be an anti-reflection (AR) coating formed of silicon dioxide, silicon nitride or combinations thereof. Gridlines 220 are electrically connected to substrate 240 through dielectric layer 230. This typically occurs due to etching during firing of the screen printed PV cell.

Gridline 220 collects and conducts electricity to busbar 210. Busbar 210 electrically connects PV cell to another. Gridline 220 and/or busbar 210 can be formed of a metal matrix composite comprised of a metal matrix and a plurality of carbon nanotubes. The metal matrix can be a metal paste including, for example, silver, copper, gold, aluminum or mixtures thereof. The carbon nanotubes can be multi-walled carbon nanotubes. Although single walled carbon nanotubes can be used, they are more difficult to produce and therefore more expensive. The multi-walled carbon nanotubes can have a length of about 10 μm to about 100 μm, about 15 μm to about 50 μm, or about 15 μm to about 20 μm. The multi-walled carbon nanotubes can be distributed randomly throughout the metal matrix and comprise about 0.1 wt % to about 10 wt % of the metal matrix composite. Optionally the multi-walled carbon nanotubes can comprise about 1 wt % to about 4 wt % of the metal matrix composite.

The metal matrix composite contact can have an increased modulus of toughness of 16% to 200% compared to a contact formed only of the metal. The metal matrix composite contact can further have an elastic modulus 9 times greater than a contact formed only of the metal. And, the metal matrix composite contact can have a 10 fold increase in fracture strength compared to a contact formed only of the metal.

The metal matrix composite contact also provides self-healing capability. FIG. 3 schematically depicts a gridline 320 including a crack that physically separates gridline 320 by a gap 329. Gap 329 physically and/or electrically separates a first portion 321 of gridline 320 from a second portion 322 of gridline 320. A crack can develop by thermomechanical stress during transportation, installation, and operation. These cracks can then lead to hot spots during module operation. A plurality of multi-walled carbon nanotubes 325 of the metal matrix composite forming gridline 320, however, allow gridline 320 to retain electrically continuity. The plurality of multi-walled carbon nanotubes 325 can electrically bridge gaps of about 50 μm or more, or about 4 μm to about 20 μm.

Metal Matrix Composite Contact Example

To demonstrate property improvement, gap bridging, and self-healing capabilities, reference contacts and metal matrix composite contacts were screen printed and tested. Metal matrix composite contacts were formed using the metal matrix composite pastes disclosed above. The multi-walled carbon nanotubes were obtained from Cheap Tubes, Inc. (Cambridgeport, Vt.) and had an outer diameter of 30-50 nm and a length of 10-20 μm. Three silver pastes produced by E. I. du Pont de Nemours and Company (Wilmington, Del.) were used: (1) Paste A—Dupont PV19L; (2) Paste B—Dupont PV76A; and, (3) Paste C—Dupont PV3N2. Using the multi-walled carbon nanotubes and the silver pastes, metal matrix composite pastes were formed as described herein.

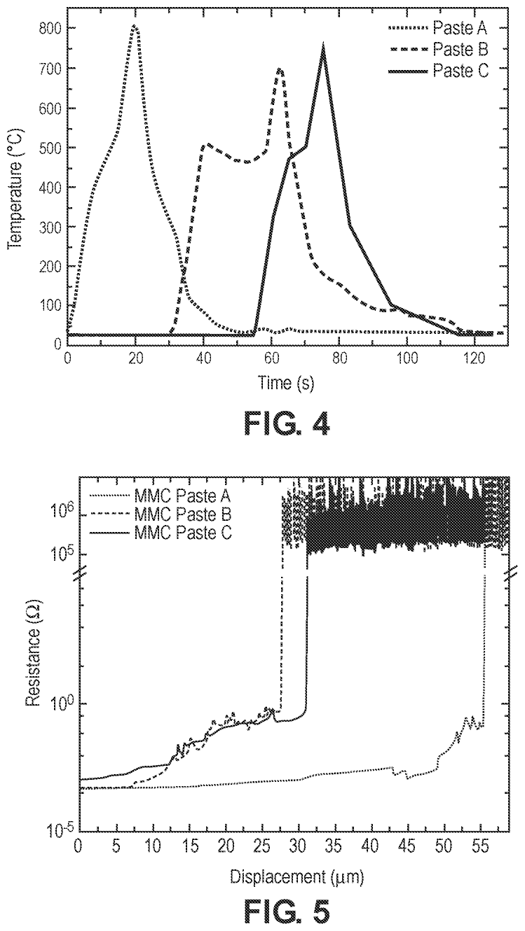

Test and reference cells having a dimension of 2 inches×2 inches were then formed by screen printing. Reference contacts were screen printed on reference cells using silver pastes A, B, and C. Test contacts were screen printed on test cells using the three metal matrix composite pastes. Screen printing was accomplished using an Accu-Coat 3230 semi-manual screen printer from Aremco Products, Inc. (Valley Cottage, N.Y.) and stainless-steel wire screen from Cefar Inc. The screen had a 400 mesh count, a 0.7 mil wire diameter, a 22.5° wire angle, and an S24 emulsion type. The test and reference contacts having line widths of 2.4 mm and 60 μm were printed on an indium phosphate (InP) substrate. After screen printing, the contacts on the test and reference cells were fired in a quartz tube furnace using the heating profiles shown in FIG. 4.

To evaluate gap bridging, the test and reference cells were mounted on printed circuit boards and a crack was generated on the back side of the InP substrate in an orthogonal direction to contacts, using a diamond scribe. The cracked test and reference cells were then transferred to a linear stage and secured using an epoxy adhesive. After a curing period, each test and reference contact was connected through a power resistor (10Ω rated for 25-W maximum dissipated power) to a DC power source. All test lines had a common ground. A data acquisition unit, National Instruments Voltage Input Module model NI-9228 (Austin, Tex.), was used to monitor the voltage drop across each test and reference contact. The voltage drop was recorded to determine the current flow through the individual test and reference contacts. The applied bias across the entire assembly was 6 VDC. Once the potential was applied, the test and reference contacts were strained at sub-micron increments until the electrical continuity was lost.

For the reference cells having contacts formed from silver pastes A, B, and C, electrical continuity was lost immediately and irrecoverably upon crack formation. FIG. 5 plots electrical resistance versus displacement (also referred to herein as crack or gap size) for the test cells formed of the metal matrix composites. As evident from FIG. 5, the metal matrix composite contacts were able to maintain electrical continuity after cracking. The test cell having contacts formed from the metal matrix composite including Paste A bridged a gap over 50 μm. The test cell having contacts formed from the metal matrix composite including Paste B bridged a gap over 27 μm. And, the test cell having contacts formed from the metal matrix composite including Paste C bridged a gap over 32 μm.

These results show that contacts formed from the metal matrix composite are capable of electrically bridging gaps (>50 μm) well beyond the lengths of the embedded multi-walled carbon nanotubes (10-20 μm). While not wishing to be bound by any particular theory, this may result from three possible reasons. First, the multi-walled carbon nanotubes, are deposited in a relaxed state, tend to be flexible yarn-like fibers rather than rigid tubes. When stretched, the multi-walled carbon nanotubes straighten and in some cases elongate. Second, the multi-walled carbon nanotubes consist of concentric cylindrical layers of graphite sheets, where the intershell interaction is dominated by weak van der Waals forces. The individual cylinders of multi-walled carbon nanotubes can slide or rotate with respect to each other when mechanically pulled causing a telescoping behavior. Third, the metal matrix composite contacts are more ductile than conventional metallization, ultimately resulting in plastic deformation during fiber pullout. That is, the metal at the anchor points of carbon nanotubes can be stretched out. Some or all of these characteristics may contribute to the enhanced gap-bridging capability beyond the individual lengths of carbon nanotubes when the metal matrix composite contacts are stretched.

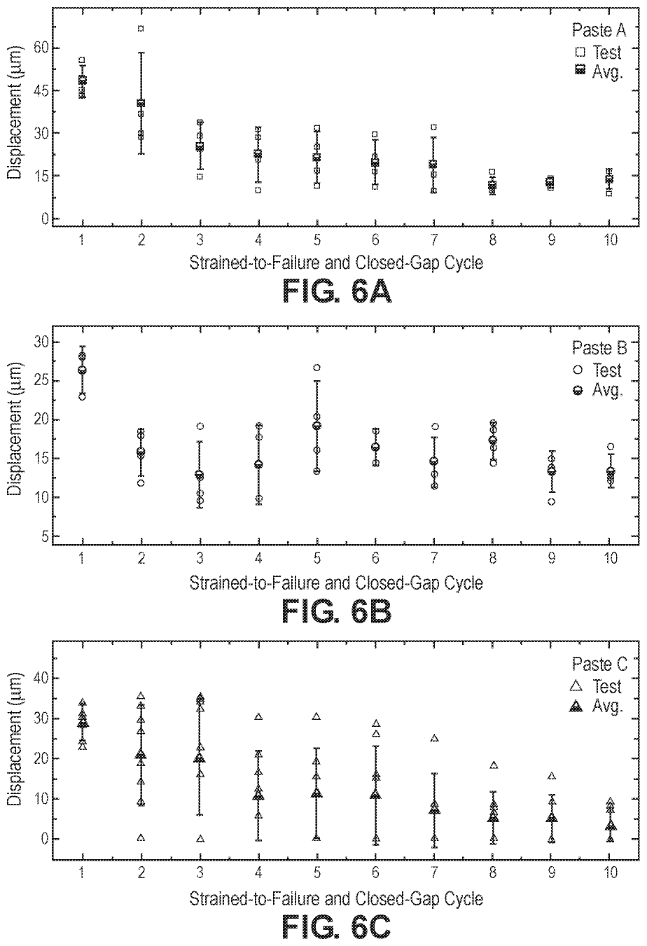

In addition to gap bridging capability, the contacts formed from the metal matrix composite “self-heal” once the gap is closed and re-establish their electrical connection. In contrast, the reference cells having contacts formed from just the silver pastes failed irreversibly upon crack formation and did not regain electrical continuity when the gap was closed. FIGS. 6A-C show that a cycle of strained-to-failure and closed-gap self-healing is repeatable for the contacts formed from the metal matrix composite. For example, FIG. 6A shows a self-healing bridgeable gap of about 15 to about 20 μm after multiple strained-to-failure and closed-gap cycles for the contacts formed from the metal matrix composite including Paste A. FIG. 6B shows a self-healing bridgeable gap of about 10 to about 15 μm after multiple strained-to-failure and closed-gap cycles for the contacts formed from the metal matrix composite including Paste B. And, FIG. 6C shows a self-healing bridgeable gap of about 15 μm after multiple strained-to-failure and closed-gap cycles for the contacts formed from the metal matrix composite including Paste C.

To evaluate the fracture strength, elastic modulus, and modulus of toughness, free-standing reference contacts and metal matric composite test contacts were formed from the three silver pastes and the three metal matrix composite pastes in free standing form. Each of the three silver pastes and the three metal matrix composite pastes were screen printed on a silicon (Si) substrate to a length of 10 to 22 mm and a width of 2.5 mm. The screen printed reference contacts and metal matrix composite test contacts were delaminate from the Si substrate to form free-standing metal matrix composite test contacts and silver reference contacts by firing them in a nitrogen-rich atmosphere. The reference contacts and metal matrix composite test contacts were then mounted in a Dynamic Mechanical Analysis (DMA) setup. A tensile clamp was used on the DMA setup where the top clip was fixed, and the bottom clip was free to apply strain on the reference contacts and metal matrix composite test contacts. A constant strain rate of 0.05%/min was applied to the bottom clip until the reference contacts and metal matrix composite test contacts failed. A pre-load strain of 0.01% and pre-load force of 0.001 N were initially applied to take out any slack in the reference contacts and metal matrix composite test contacts. These measurements provided stress-versus-strain curves that were used to extract the elastic modulus and the modulus of toughness of Ag reference contacts and metal matrix composite test contacts as a function of CNT loading.

For the contacts formed from the metal matrix composite including Paste A, the modulus of toughness increased by 16% compared to the contact formed from just Paste A. For the contacts formed from the metal matrix composite including Paste B, the modulus of toughness and fracture strength increased by 10 fold, and the elastic modulus increased by 9 fold compared to the contact formed from just Paste B. For the contacts formed from the metal matrix composite including Paste C, the elastic modulus increased by 47% compared to the contact formed from just Paste C.

Although the metal matrix composite contacts are described herein with reference to a front or top contact of a PV cell, one of ordinary skill in the art will understand that the metal matrix composite contacts can be used throughout a PV cell, module, or system.

While the present teachings have been illustrated with respect to one or more implementations, alterations and/or modifications can be made to the illustrated examples without departing from the spirit and scope of the appended claims. For example, it will be appreciated that while the process is described as a series of acts or events, the present teachings are not limited by the ordering of such acts or events. Some acts may occur in different orders and/or concurrently with other acts or events apart from those described herein. For example, steps of the methods have been described as first, second, third, etc. As used herein, these terms refer only to relative order with respect to each other, e.g., first occurs before second. Also, not all process stages may be required to implement a methodology in accordance with one or more aspects or implementations of the present teachings. It will be appreciated that structural components and/or processing stages can be added or existing structural components and/or processing stages can be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. As used herein, the term “one or more of” with respect to a listing of items such as, for example, A and B, means A alone, B alone, or A and B. The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “about” indicates that the value listed may be somewhat altered, as long as the alteration does not result in nonconformance of the process or structure to the illustrated implementation. Finally, “exemplary” indicates the description is used as an example, rather than implying that it is an ideal. Other implementations of the present teachings will be apparent to those skilled in the art from consideration of the specification and practice of the disclosure herein. It is intended that the specification and examples be considered as exemplary only, with a true scope and spirit of the present teachings being indicated by the following claims.

What is claimed is:

1. A photovoltaic cell comprising:
a substrate;
an anti-reflection coating disposed on the substrate; and
a metal matrix composite contact disposed on the anti-reflection coating, the metal matrix composite contact comprising,
a metal, and
a plurality of multi-walled carbon nanotubes (CNTs) distributed in the metal;
wherein the metal of the metal matrix composite contact electrically connects to the substrate through the anti-reflection coating.

2. The photovoltaic cell of claim 1, wherein modulus of toughness of the metal matrix composite contact is 16% to 200% greater compared to a metal contact consisting essential of the metal without the plurality of multi-walled carbon nanotubes.

3. The photovoltaic cell of claim 1, wherein the metal matrix composite contact can electrically bridge a gap less than about 50 μm wide, from about 15 to about 40 μm, or from about 4 to about 20 μm.

4. The photovoltaic cell of claim 1, wherein the plurality of multi-walled CNTs is about 0.1 wt % to about 10 wt % of the metal matrix composite contact.

5. The photovoltaic cell of claim 1, wherein the plurality of multi-walled CNTs is about 1 wt % of the metal matrix composite contact.

6. The photovoltaic cell of claim 1, wherein the metal of the metal matrix composite contact comprises silver, copper, gold, aluminum, or combinations thereof.

7. The photovoltaic cell of claim 1, wherein the plurality of multi-walled CNTs have a length from about 10 to about 100 μm.

8. The photovoltaic cell of claim 1, wherein the contact is a gridline or bulbar in a photovoltaic device.

9. The photovoltaic cell of claim 8, wherein the plurality of multi-walled CNTs are randomly oriented with respect to the gridlines or busbars.

10. A method for forming a paste for screen printing contacts, the method comprising;
providing a plurality of multi-walled carbon nanotubes;
functionalizing a surface of the plurality of multi-walled carbon nanotubes to form a plurality of functionalized multi-walled carbon nanotubes; and
mixing the plurality of functionalized multi-walled carbon nanotubes with a metal paste to form a metal matrix composite (MMC) paste.

11. The method of claim 10 further comprising forming a solution comprising the plurality of functionalized multi-walled carbon nanotubes and a solvent prior to mixing the plurality of functionalized multi-walled carbon nanotubes with a metal paste.

12. The method of claim 11, further comprising heating the metal matrix composite paste to match a viscosity of the metal matrix composite paste to a viscosity of the metal paste or to increase the viscosity of the metal matrix composite paste.

13. The method of claim 10 wherein functionalizing the surface of the plurality of multi-walled carbon nanotubes comprises functionalizing the surface of the plurality of multi-walled carbon nanotubes with carboxylic or amine functional groups.

14. The method of claim 13 wherein functionalizing the surface of the plurality of multi-walled carbon nanotubes with carboxylic functional groups comprises;
forming a mixture comprising the multi-walled carbon nanotubes and one or more acids;
heating the mixture and sonicating the mixture;
forming a solution by adding the mixture to water;
filtering the solution to collect the multi-walled carbon nanotubes;
washing the multi-walled carbon nanotubes to remove residual acid; and
drying the multi-walled carbon nanotubes to form carboxylated carbon nanotubes.

15. The method of claim 14 wherein the one or more acids comprise nitric acid (HNO₃), sulfuric acid (H₂SO₄) or a combination thereof.

16. A metal matrix composite paste comprising;
a metal paste;
a plurality of multi-walled carbon nanotubes, wherein a surface of the plurality of multi-walled carbon nanotubes is functionalized with carboxylic or amine functional groups.

17. The metal matrix composite paste of claim 16, wherein the metal paste comprises silver, copper, gold, aluminum, or combinations thereof.

18. The metal matrix composite paste of claim 16, wherein the plurality of multi-walled carbon nanotubes is about 0.1 wt % to about 10 wt % of the metal matrix composite paste.

19. A method for forming an electrical contact in a photovoltaic device comprising;
providing a substrate;
depositing a dielectric layer on the substrate;
screen printing on the dielectric layer a metal matrix composite paste comprising a metal paste and a plurality of multi-walled carbon nanotubes, wherein a surface of the multi-walled carbon nanotubes is functionalized with carboxylic or amine functional groups; and
firing the metal matrix composite paste to form an electrical contact.

20. The method of claim 19, wherein the electrical contact comprises a plurality of multi-walled carbon nanotubes distributed in a metal matrix.

21. The method of claim 19, wherein firing further comprises etching through the dielectric layer so the metal matrix composite paste electrically connects to the substrate.

22. The method of claim 19, wherein the substrate comprises silicon and the metal paste comprises silver.
